(19) United States
(12) Patent Application Publication
(10) Pub. No.: US 2015/0155462 A1
(43) Pub. Date: Jun. 4, 2015

(54) Printed Semiconductor Junctions

(71) Applicant: Evident Technologies, Troy, NY (US)

(72) Inventors: Susanthri Perera, Cohoes, NY (US); Bed Poudel, Newtonville, MA (US); Clinton T. Ballinger, Burnt Hills, NY (US); Gregg Bosak, Hoosick Falls, NY (US); Adam Z. Peng, Schenectady, NY (US)

(21) Appl. No.: 14/559,298

(22) Filed: Dec. 3, 2014

Related U.S. Application Data
(60) Provisional application No. 61/911,143, filed on Dec. 3, 2013.

(51) Int. Cl. H01L 35/08; H01L 35/34

(52) U.S. Cl. CPC H01L 35/08; H01L 35/34

(57) ABSTRACT

Disclosed herein is a thermoelectric module and a method of producing a thermoelectric module via printing techniques. The method can include providing a first ink, the first ink including a first population of n-material semiconductor nanomaterials suspended in a solvent, and providing a second ink, the second ink including a second population of p-material semiconductor nanomaterials suspended in a solvent. Further, the method can include printing the first ink and the second ink on a substrate and applying a conducting layer electronically contacting both the first ink and the second ink printed on the substrate. The method may also include heating the substrate

### FIELD OF THE INVENTION

Embodiments of the present invention relate generally to methods of producing thermoelectric elements through a printed semiconductor ink.

### BACKGROUND OF THE INVENTION

Thin film thermoelectric devices are currently manufactured using a set of traditional semiconductor processing techniques, which may include lithography of various types, vacuum deposition techniques, and others. Alternatively, they may be produced using a traditional pillar technique that is used in most thermoelectric modules. In these techniques, pillars of positive (“p-type”) material and pillars of negative (“n-type”) material are interconnected with a conductor to form a junction. However, these known methods are both expensive and time consuming.

### BRIEF DESCRIPTION OF THE INVENTION

Embodiments of the invention disclosed herein may include a method of producing a thermoelectric module via printing techniques, the method comprising: providing a first ink, the first ink including a first population of n-material semiconductor nanomaterials suspended in a solvent; providing a second ink, the second ink including a second population of p-material semiconductor nanomaterials suspended in a solvent; printing the first ink and the second ink on a substrate; applying a conducting layer electronically contacting both the first ink and the second ink printed on the substrate; and heating the substrate.

Embodiments of the invention may also include a thermoelectric module produced by a method utilizing printing techniques, the method comprising: providing a first ink, the first ink including a first population of n-material semiconductor nanomaterials suspended in a solvent; providing a second ink, the second ink including a second population of p-material semiconductor nanomaterials suspended in a solvent; printing the first ink and the second ink on a substrate; applying a conducting layer electronically contacting both the first ink and the second ink printed on the substrate; and heating the substrate.

### BRIEF DESCRIPTION OF THE FIGURES

FIG. 1 illustrates a thin film p-material printed on a substrate according to certain embodiments of the present invention.

FIG. 2 shows an example embodiment of a printed junction according to embodiments of the present invention.

FIG. 3 shows an example embodiment of a different printed junction according to embodiments of the present invention.

FIG. 4 shows an example embodiment of a zigzag designed printed junction according to embodiments of the present invention.

### DETAILED DESCRIPTION OF THE INVENTION

Many applications for thin film thermeoelectrics can be cost sensitive in nature. Such thin film thermoelectric applications can include micro-power waste heat recovery and high heat flux cooling applications. Both of these markets are large and may require inexpensive thermoelectric modules to be fully realized. Embodiments of the present invention address this issue and can lead to a significant cost reduction in the final thermoelectric modules.

In some embodiments, a new method includes a printed thermoelectric module. In said embodiments, it can be possible to print a semiconductor material, which may include a semiconductor nanocrystal which is typically suspended in a solvent, which can be formulated into an ink, onto a substrate that is heated during application of the semiconductor nanocrystal inks The heating drives off the solvent that is suspending the semiconductor particles and can thus aid in creating a thin film of semiconductor material. While heating is used in many examples below, including placing the substrate on a hot plate or heated surface, as well as under a heat lamp or other heat source, it should be understood that the substrate may be dried in a number of ways, including but not limited to vacuum drying, flash lamp sintering, and other drying techniques known in the art. This film can vary in thickness from sub-micron ranges up to hundreds of microns thick. The thickness of the material impacts the performance of the final device, and the ability to print a variety of thicknesses can greatly increase the applicable fields of use of the thermoelectric modules printed with such methods.

The term “print” refers to a variety of techniques utilized to deposit a known amount of semiconductor material onto the substrate, typically in the form of an ink. It can include methods known in the art such as air brushing, ink jetting, gravure rolling, flexographic printing, offset printing, screen printing, and any other now known or later developed method of depositing semiconductor material in a solvent on a thin substrate.

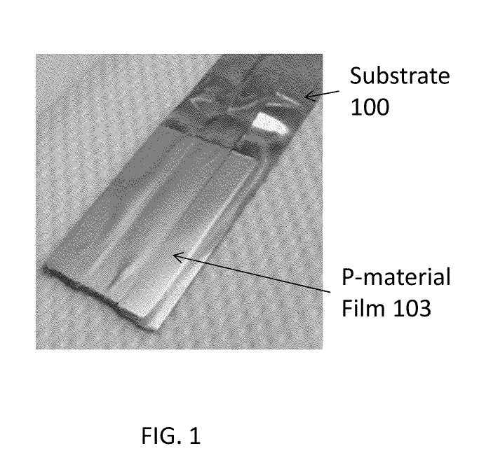

A colloidal suspension or other forms of suspension of nano-sized semiconductor materials can be considered an ink. This ink may consist of a solvent which is designed to suspend the semiconductor particles and any other solid particles, which may include further semiconductors, metals, insulators, and mixtures thereof. The solvent can include hydrazine, hydrazine hydrate, DMSO, toluene, hexane, and other solvents that can be evaporated upon heating. The solvent may include the solvent that was used to grow the nanomaterials, especially in the case of colloidal nanomaterials or colloidal quantum dots. The ink can be used to print semiconductor junctions that form the basic elements of most modern solid-state devices. For instance, using these methods p and n type junctions can be printed by using two different inks, one a p-type material and the other an n-type material, in order to form the basic building blocks for a thermoelectric device, as one example. As illustrated in FIG. 1, in one embodiment, a p-type semiconductor thin film may be airbrushed onto a substrate such as a thin film metal substrate or an insulated substrate, which may have a conductive layer over the substrate.

Upon printing the inks onto a substrate, the printed semiconductor elements can be fashioned into thermoelectric modules in a variety of ways. The material may be printed onto a thermally and electrically insulating substrate; however conductive substrates can also be used for some embodiments. In the following examples, which are not meant to be limiting, insulating substrates are shown. These insulating substrates can be made of glass, plastic, kapton tape (or other polyimides), paper, ceramics, or a variety of other insulating or non-conductive materials known to be effective substrates for thermoelectric applications. The inks may be applied by spraying only certain portions of the substrate, by masking the substrate, or by cutting a substrate upon which inks have been printed into particular shapes.

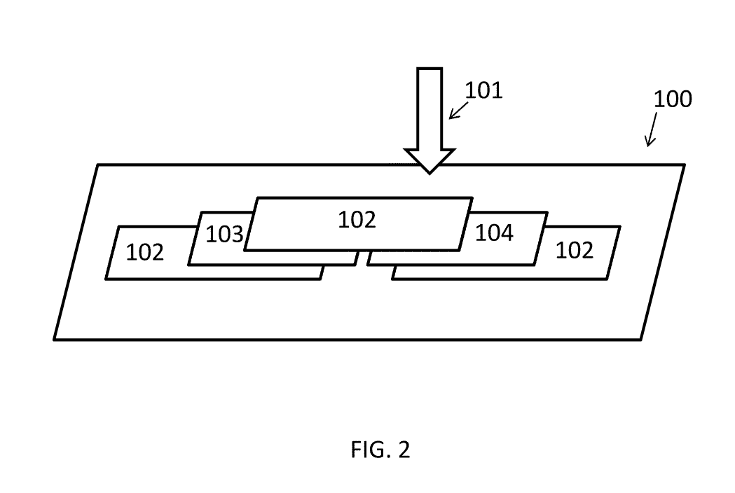

FIG. 2 illustrates an embodiment utilizing substrate 100, described above, with heating of the resulting thermoelectric module, or a heat flux 101, illustrated as an arrow, is applied perpendicular to the plane of the surface of substrate 100 to which the semiconductor material inks are applied. In these embodiments, conducting layers 102, p-material ink 103, and n-material ink 104 are stacked, with the side with the inks being the hot side, and the underside (not shown) being the cold side of substrate 100 and any device thus used. Embodiments utilizing the design illustrated in FIG. 2 can be used for a number of different device types, including but not limited to waste heat recovery, power generation from heat, and heating/cooling applications. The thin layers of p-material ink 103 and n-material ink 104 are interconnected in a thermoelectric circuit design via a conductive material of conducting layers 102, which is typically a metal. Conducting layers 102 can be ITO, gold, copper, silver, aluminum, nickel, lead-based solders, other solders, solder pastes, molybdenum disulfide (MoS₂), graphene, conductive inks, or other materials and combinations thereof. According to embodiments of this design, applications may include those similar to traditional thin film thermoelectric devices, such as high heat flux applications including cooling hot materials. Applications can also include waste heat recovery or power generation from heated materials.

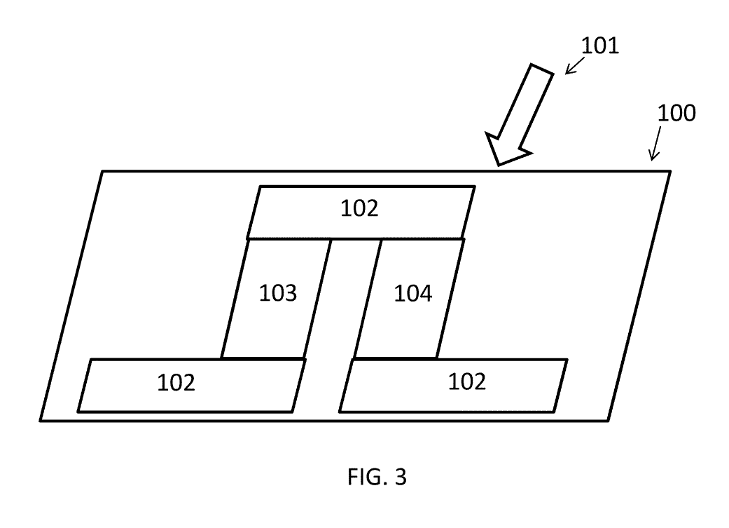

In other embodiments, as illustrated in FIG. 3, an example of a design where, the heat applied to the resulting thermoelectric module, or the heat flux 101, is applied parallel to the plane of the surface of substrate 100 is shown. In these embodiments, the layers are not stacked. As with the perpendicular heating of the design illustrated in FIG. 2, this design is a simple interconnect p/n junction using a conductive material which connects the p and n materials, but without being layered. All of these materials can be printed using any of the aforementioned printing techniques. In addition, the substrate can be made of insulating or conducting material.

In another embodiment, the printed material can be removed from the substrate using typical processing techniques. According to embodiments of this design, applications may include waste heat recovery or power generation from heated materials. Applications can also include high heat flux applications including cooling hot materials.

Referring back to FIGS. 2 and 3, as would be understood to one of skill in the art, the voltage and current of the resulting thermoelectric module can be controlled in terms of both voltage and current based on the design, whether stacked or unstacked, as well as the width and length of the layers formed, as well as the number of layers used.

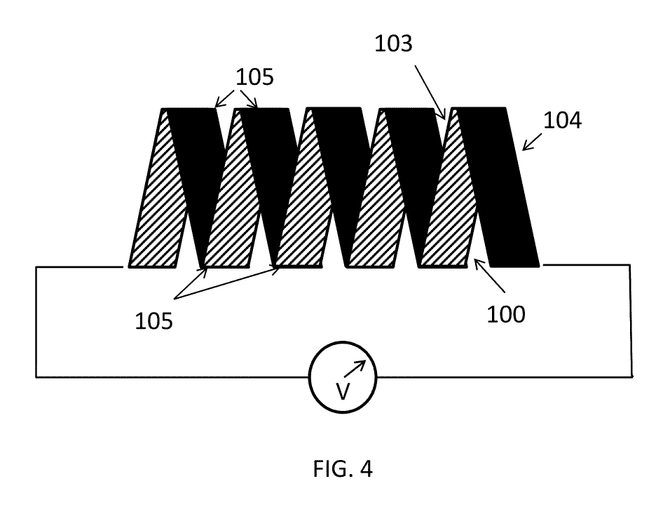

In other embodiments, as illustrated in FIG. 4, the p and n thin films can be connected directly through a soldering process. In these embodiments, this technique may include the use of an insulating substrate 100, examples of which are disclosed above, in order to keep the layers from electrically connecting at locations other than the desired junction. FIG. 4 shows an example of printed p-material ink 103 and n-material ink 104 on insulating substrate 100 that are interconnected via a soldering process to form a series of p/n junctions 105 on the relative top and bottom of the device. Junctions 105 may include any material now known or later developed capable of forming a junction between p-material and n-material layers. In these embodiments, the top side can be considered the hot side and the bottom side can be considered the cold side. As illustrated, voltage and current can be generated from such a thermoelectric module from one side to the other. In such embodiments, the surface area of a thermoelectric module can be greatly increased due to the folded shape, whilst taking up a relatively small three dimensional space within the device. Increasing the number of junctions, and thus p-material and n-material layers, or the height of each p-material and n-material layer, can alter both the voltage and current derived from the thermoelectric module produced therein. In embodiments where the folded layers are closer together, a spacer or insulator may be utilized to prevent contact of the p-material and n-material layers on the top side of substrate 100.

Demonstrated in the disclosure are a number of methods to produce a multi-junction thermoelectric module and can give the flexibility to control the current and voltage characteristics by adding more junctions and/or by changing the shape and size of each p and n printed region.

The foregoing description of various aspects of the invention has been presented for the purpose of illustration and description. It is not intended to be exhaustive or to limit the invention to the precise form disclosed, and obviously, many modifications and variations are possible. Such variations and modifications that may be apparent to one skilled in the art are intended to be included within the scope of the present invention as defined by the accompanying claims.

What is claimed:

1. A method of producing a thermoelectric module via printing techniques, the method comprising:
providing a first ink, the first ink including a first population of n-material semiconductor nanomaterials suspended in a solvent;
providing a second ink, the second ink including a second population of p-material semiconductor nanomaterials suspended in a solvent;
printing the first ink and the second ink on a substrate;
applying a conducting layer electronically contacting both the first ink and the second ink printed on the substrate; and
heating the substrate.

2. The method of claim 1, wherein the conducting layer comprises: ITO, gold, copper, silver, aluminum, nickel, lead-based solders, other solders, solder pastes, molybdenum disulfide (MoS₂), graphene, conductive inks, or a combination thereof.

3. The method of claim 1, wherein at least one of the first ink and the second ink further comprises at least one of: a different semiconductor, a metal, an insulator, and a mixture thereof.

4. The method of claim 1, wherein the substrate comprises one of: glass, plastic, kapton, paper, or ceramics.

5. The method of claim 1, wherein the substrate includes a conductive material.

6. The method of claim 1, wherein the thermoelectric module is used in an application involving a heat flux applied in a direction perpendicular relative to a plane of a surface of the substrate.

7. The method of claim 1, wherein the thermoelectric module is used in an application involving a heat flux applied in a direction parallel relative to a plane of a surface of the substrate.

8. A thermoelectric module produced by a method utilizing printing techniques, the method comprising:
providing a first ink, the first ink including a first population of n-material semiconductor nanomaterials suspended in a solvent;
providing a second ink, the second ink including a second population of p-material semiconductor nanomaterials suspended in a solvent;
printing the first ink and the second ink on a substrate;
applying a conducting layer electronically contacting both the first ink and the second ink printed on the substrate; and
heating the substrate.

9. The thermoelectric module of claim 8, wherein the conducting layer comprises: ITO, gold, copper, silver, aluminum, nickel, lead-based solders, other solders, solder pastes, molybdenum disulfide (MoS₂), graphene, conductive inks, or a combination thereof.

10. The thermoelectric module of claim 8, wherein at least one of the first ink and the second ink further comprises at least one of: a different semiconductor, a metal, an insulator, and a mixture thereof.

11. The thermoelectric module of claim 8, wherein the substrate comprises one of: glass, plastic, kapton, paper, or ceramics.

12. The thermoelectric module of claim 8, wherein the substrate includes a conductive material.

13. The thermoelectric module of claim 8, wherein the thermoelectric module is used in an application involving a heat flux applied in a direction perpendicular relative to a plane of a surface of the substrate.

14. The thermoelectric module of claim 8, wherein the thermoelectric module is used in an application involving a heat flux applied in a direction parallel relative to a plane of a surface of the substrate.
